(19) United States
(12) Patent Application Publication
(10) Pub. No.: US 2021/0061651 A1
(43) Pub. Date: Mar. 4, 2021

(54) MEMS MICROPHONE

(71) Applicant: TOPPAN PRINTING CO., LTD., Tokyo (JP)

(72) Inventors: Yasuko GOTOH, Tokyo (JP); Hiroyuki CHIKAMORI, Tokyo (JP); Naohiro NOMURA, Tokyo (JP); Naoki INAGAKI, Tokyo (JP)

(73) Assignee: TOPPAN PRINTING CO., LTD., Tokyo (JP)

(21) Appl. No.: 17/095,372

(22) Filed: Nov. 11, 2020

Related U.S. Application Data
(63) Continuation of application No. PCT/JP2019/019108, filed on May 14, 2019.

(30) Foreign Application Priority Data
May 15, 2018 (JP) 2018-093572

(51) Int. Cl. B81C 1/00; H04R 19/04

(52) U.S. Cl. CPC B81C 1/00158; H04R 19/04; B81B 2201/0257; B81B 2203/0127; H04R 2201/003

(57) ABSTRACT

A MEMS microphone includes: a glass substrate including an opening portion; a membrane provided on the glass substrate so as to cover the opening portion and including a first conductive layer; and a backplate provided above the membrane via a cavity, including a plurality of through holes through which sound waves pass, and including a second conductive layer. The first conductive layer is made of a metal or a conductive oxide. The second conductive layer is made of a metal or a conductive oxide.

### CROSS-REFERENCE TO RELATED APPLICATIONS

This application is a Continuation Application of PCT Application No. PCT/JP2019/019108, filed May 14, 2019, and based upon and claiming the benefit of priority from Japanese Patent Application No. 2018-093572, filed May 15, 2018, the entire contents of all of which are incorporated herein by reference.

### FIELD

The present invention relates generally to a MEMS microphone for detecting sound.

### BACKGROUND

In a general MEMS microphone, an element is formed on a semiconductor substrate (e.g., a silicon substrate). The MEMS microphone can be miniaturized by utilizing a semiconductor manufacturing technology. The MEMS microphone includes a backplate electrode having a plurality of through holes and a membrane electrode (diaphragm electrode) that vibrates in accordance with sound pressures caused by sound waves. When the membrane electrode vibrates due to the sound pressure, a capacitance between the backplate electrode and the membrane electrode changes. The MEMS microphone detects sound by detecting a voltage change corresponding to the capacitance change.

### SUMMARY

According to an aspect of the present invention, there is provided a MEMS microphone comprising:

a glass substrate including an opening portion;

a membrane provided on the glass substrate so as to cover the opening portion and including a first conductive layer; and

a backplate provided above the membrane via a cavity, including a plurality of through holes through which sound waves pass, and including a second conductive layer,

wherein

the first conductive layer is made of a metal or a conductive oxide, and

the second conductive layer is made of a metal or a conductive oxide.

### BRIEF DESCRIPTION OF THE DRAWINGS

FIG. 1 is a plan view of a MEMS microphone according to a first embodiment.

FIG. 2 is a bottom view of the MEMS microphone shown in FIG. 1.

FIG. 3 is a cross-sectional view of the MEMS microphone taken along line A-A′ shown in FIG. 1.

FIG. 4 is a cross-sectional view of the MEMS microphone taken along line B-B′ shown in FIG. 1.

FIG. 5 is a cross-sectional view of the MEMS microphone taken along line C-C′ shown in FIG. 1.

FIG. 6 is a diagram for explaining resistivities of a plurality of substances.

FIG. 7 is a cross-sectional view of a MEMS microphone according to a second embodiment.

FIG. 8 is a cross-sectional view of the MEMS microphone according to the second embodiment.

FIG. 9 is a cross-sectional view of the MEMS microphone according to the second embodiment.

FIG. 10 is plan views of a backplate electrode, a membrane electrode, and an opening portion of a glass substrate according to a third embodiment.

FIG. 11 is a cross-sectional view of a MEMS microphone according to a fourth embodiment.

FIG. 12 is plan views of a backplate electrode, a membrane electrode, and an opening portion of a glass substrate according to the fourth embodiment.

### DETAILED DESCRIPTION

Hereinafter, embodiments will be described with reference to the drawings. Note that the drawings are schematic or conceptual, and the dimensions and proportions of the drawings are not necessarily the same as the actual ones. Furthermore, even when parts shown in the drawings indicate the same part, they may be expressed with different dimensional relationships or ratios. Several embodiments described below merely show exemplary apparatuses and methods for implementing the technical ideas of the present invention, and the technical ideas are not limited by the element shapes, structures, arrangements, etc. described below. In the description below, structural elements having the same functions and configurations will be denoted by the same reference symbol, and a repetitive description of such elements will be given only where necessary.

The following embodiment is a configuration example of a MEMS microphone. MEMS (Micro Electro Mechanical Systems) is a device in which an electric circuit and a fine mechanical structure are integrated on one substrate.

### [1] First Embodiment

### [1-1] Configuration of MEMS Microphone 10

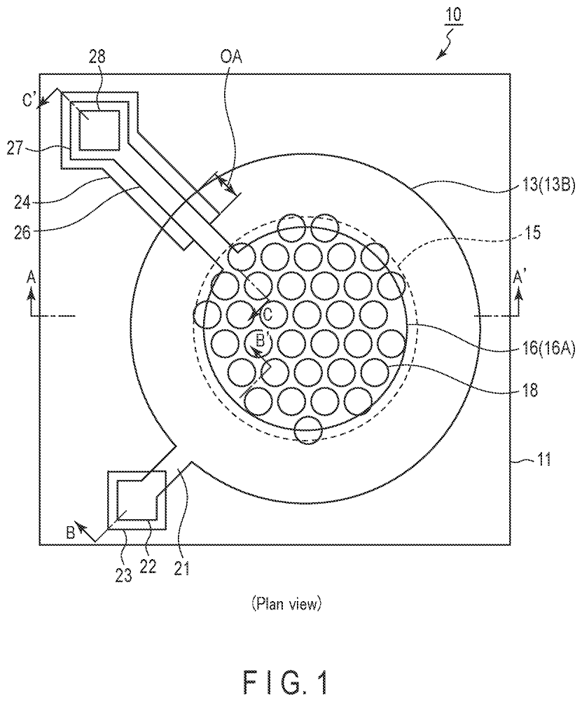

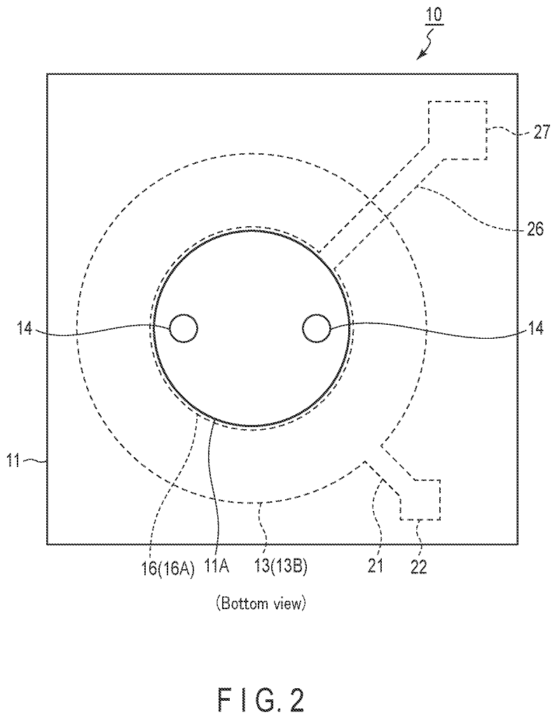

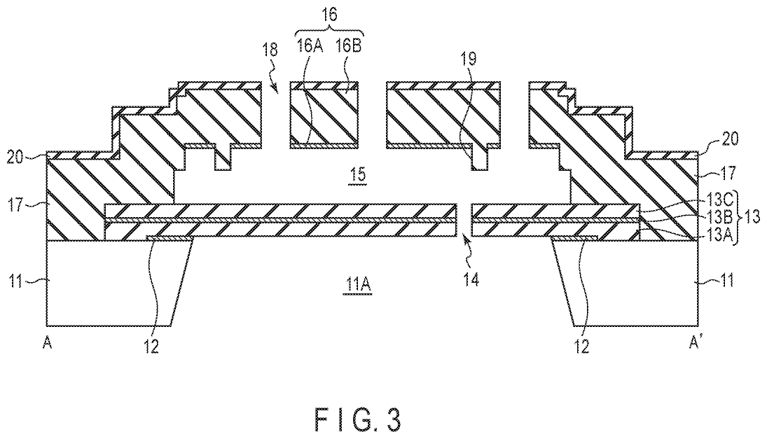

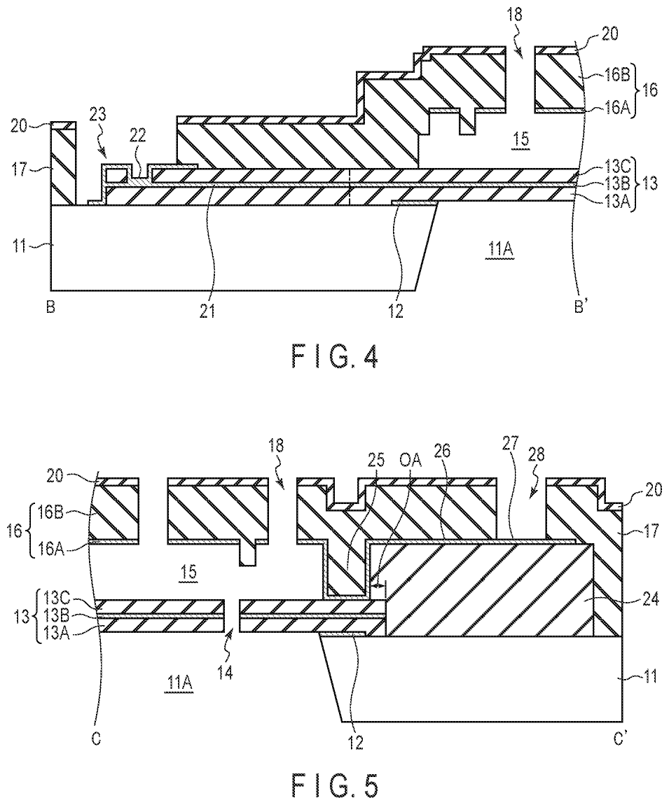

FIG. 1 is a plan view of a MEMS microphone 10 according to the first embodiment. FIG. 2 is a bottom view of the MEMS microphone 10 shown in FIG. 1. FIG. 3 is a cross-sectional view of the MEMS microphone 10 taken along line A-A′ shown in FIG. 1. FIG. 4 is a cross-sectional view of the MEMS microphone 10 taken along line B-B′ shown in FIG. 1. FIG. 5 is a cross-sectional view of the MEMS microphone 10 taken along line C-C′ shown in FIG. 1.

A general MEMS is formed using a semiconductor material and a semiconductor manufacturing technology. In addition, in the general MEMS, a silicon substrate is used so that microfabrication is advantageous. In contrast, in the present embodiment, a glass substrate 11 is used as a substrate of the MEMS microphone 10. The glass substrate 11 has an insulating property. As the glass substrate 11, for example, alkali-free glass is used. The glass substrate 11 is approximately 0.5 mm thick. The planar shape of the glass substrate 11 is, for example, a quadrangle. The present embodiment uses the glass substrate 11 for the MEMS microphone 10, so is different in laminated structure from the general MEMS using a silicon substrate.

The glass substrate 11 includes an opening portion 11A. The opening portion 11A has a circular shape. The diameter of the opening portion 11A is approximately 1 mm. The opening portion 11A has, for example, a tapered shape such that the diameter continuously decreases from a lower surface side toward an upper surface side. The opening portion 11A shown in FIG. 2 shows the diameter (i.e., the minimum diameter) of the upper surface side of the glass substrate 11.

A protective layer 12 is provided on the glass substrate 11. The protective layer 12 is formed so as to surround the periphery of the opening portion 11A of the glass substrate 11. In FIGS. 1 and 2, the protective layer 12 is not shown. The protective layer 12 is made of a metal such as chromium (Cr). The opening portion 11A of the glass substrate 11 is formed by wet etching using a solution containing hydrofluoric acid. The protective layer 12 has a function of preventing a membrane to be described later from being eroded by the solution in a wet etching step.

A membrane (also referred to as a diaphragm) 13 is provided on the glass substrate 11 and the protective layer 12 so as to cover the opening portion 11A. The membrane 13 has a circular shape. The size of the membrane 13 is larger than that of the opening portion 11A of the glass substrate 11. The size of the opening portion 11A is of the upper surface side of the glass substrate 11. The membrane 13 has a three-layered structure in which an insulating layer 13A, a conductive layer 13B, and an insulating layer 13C are sequentially stacked. The conductive layer 13B functions as an electrode (vibration electrode) of the membrane 13. The conductive layer 13B is made of a metal, for example, molybdenum (Mo) having a film thickness of about 35 nm. As the conductive layer 13B, chromium (Cr), aluminum (Al), etc. may be used. Alternatively, conductive oxides such as indium tin oxides (ITO) may be used as the conductive layer 13B. Each of the insulating layer 13A and the insulating layer 13C is made of, for example, silicon nitride (SiNx) having a film thickness of about 250 nm. “x” in the chemical formula means that the composition ratio is discretionary.

The membrane 13 includes at least one through hole 14. FIG. 2 shows two through holes 14 as an example. In FIG. 3, one through hole 14 is exemplified for the sake of simplicity. The through hole 14 has a function of, in a case where a sudden sound pressure is applied to the membrane 13, releasing the sound pressure to prevent the membrane 13 from being damaged.

A backplate 16 is provided above the membrane 13 via a cavity 15. The backplate 16 is formed by sequentially stacking a conductive layer 16A and an insulating layer 16B. The conductive layer 16A functions as an electrode (fixed electrode) of the backplate 16. The conductive layer 16A is made of a metal, for example, molybdenum (Mo) having a film thickness of about 35 nm. As the conductive layer 16A, chromium (Cr), aluminum (Al), etc. may be used. Alternatively, conductive oxides such as indium tin oxides (ITO) may be used as the conductive layer 16A. The insulating layer 16B is made of, for example, silicon nitride (SiNx) having a film thickness of about 2000 nm.

The above-described cavity 15 is provided between the membrane 13 and the backplate 16. The cavity 15 is approximately 3 μm thick. The cavity 15 is surrounded by the insulating layer 17. In other words, the insulating layer 17 includes the cavity 15. The insulating layer 17 is provided on the entire region of the glass substrate 11 excluding the cavity 15. The insulating layer 17 and the insulating layer 16B of the backplate 16 are continuous layers, and are integrally formed. That is, the insulating layer 17 and the insulating layer 16B are provided on approximately the entire surface of the glass substrate 11.

The backplate 16 includes a plurality of through holes 18. The through holes 18 are provided over the entire surface of the backplate 16. In FIG. 3, three through holes 18 are exemplified for the sake of simplicity. The through holes 18 have a function of passing a sound wave applied from a side of the backplate 16 opposite to the membrane 13 to the cavity 15. Since the backplate 16 includes many through holes 18, vibration of the backplate 16 in accordance with the sound pressure can be suppressed. That is, the conductive layer 16A of the backplate 16 functions as a fixed electrode.

A plurality of protrusions 19 are provided on the membrane 13 side of the backplate 16. Although FIG. 3 shows two protrusions 19 as an example, the number of protrusions 19 can be set discretionarily. The protrusions 19 have a function of preventing the backplate 16 and the membrane 13 from coming into contact with each other. Contact between the backplate 16 and the membrane 13 may occur during operation of the MEMS microphone 10 and during the manufacturing process.

A protective layer 20 is provided on the backplate 16 and the insulating layer 17. The protective layer 20 is made of, for example, amorphous silicon having a film thickness of about 150 nm. The protective layer 20 has a function of protecting the insulating layer 16B of the backplate 16 when a sacrificial layer (e.g., silicon oxide (SiOx)) for forming the cavity 15 is removed by wet etching. The backplate 16 may include the protective layer 20. In this case, the backplate 16 has a three-layered structure in which the conductive layer 16A, insulating layer 16B, and insulating layer (protective layer) 20 are sequentially stacked.

(Configuration of Membrane Terminal)

Next, a configuration of a terminal (membrane terminal) electrically connected to the membrane 13 will be described with reference to FIGS. 1, 2, and 4.

A wiring layer 21 extending in a discretionary direction (e.g., an obliquely lower left direction in FIG. 1) is electrically connected to the conductive layer 13B of the membrane 13. The wiring layer 21 and the conductive layer 13B are continuous layers, and are integrally formed. Insulating layers are provided under and on the conductive layer 13B, respectively. The two insulating layers under and on the conductive layer 13B are respectively continuous with the insulating layers 13A and 13C of the membrane 13. A membrane terminal 22 is electrically connected to one end of the wiring layer 21. The membrane terminal 22 is exposed by an opening portion 23 formed in the insulating layer 17.

(Configuration of Backplate Terminal)

Next, a configuration of a terminal (backplate terminal) electrically connected to the backplate 16 will be described with reference to FIGS. 1, 2, and 5.

On the glass substrate 11, an insulating layer 24 extending in a discretionary direction (e.g., an obliquely upper left direction in FIG. 1) is provided. The insulating layer 24 is made of, for example, silicon oxide (SiOx). The insulating layer 24 is configured to overlap an end portion of the membrane 13. The insulating layer 24 and the cavity are partitioned by an insulating layer 25. The insulating layer 25 is made of the same material (silicon nitride (SiNx)) as that of the insulating layer 17, and is a continuous layer with the insulating layer 17.

A wiring layer 26 extending in the same direction as that of the insulating layer 24 is electrically connected to the conductive layer 16A of the backplate 16. The wiring layer 26 is provided along both side surfaces and a bottom surface of the insulating layer 25 and is provided on the insulating layer 24.

A backplate terminal 27 is electrically connected to one end of the wiring layer 26. The backplate terminal 27 is exposed by an opening portion 28 formed in the insulating layer 17.

As described above, the insulating layer 24 is formed to overlap the end portion of the membrane 13. A region where the insulating layer 24 and the membrane 13 overlap with each other is indicated by reference sign “OA” in FIGS. 1 and 5. Due to the presence of the region OA, an end portion of the conductive layer 13B of the membrane 13 and the wiring layer 26 are spaced apart. Thus, the wiring layer 26 and the conductive layer 13B of the membrane 13 can be prevented from being short-circuited.

In the region OA, a distance between the wiring layer 26 and the conductive layer 13B in the thickness direction can be increased. Thus, a parasitic capacitance in the region OA can be reduced. In FIG. 5, by reducing the width of the insulating layer 25, that is, by increasing the length of the region OA, a region where the wiring layer 26 and the conductive layer 13B face each other with the insulating layer 13C interposed therebetween can be reduced. Thus, the parasitic capacitance in the region OA can be reduced. The parasitic capacitance is a capacitance generated in a region where the membrane 13 does not vibrate.

### [1-2] Operation of MEMS Microphone 10

Next, an operation of the MEMS microphone 10 configured as described above will be described.

The MEMS microphone 10 receives sound waves (and a sound pressure caused by the sound waves) from a side of the backplate 16 opposite to the membrane 13. The backplate includes a large number of through holes 18, and the sound waves pass through the through holes 18 to the cavity 15. In addition, since the backplate 16 includes the large number of through holes 18, vibration due to a sound pressure is suppressed and the backplate 16 functions as a fixed electrode.

The membrane 13 vibrates in accordance with the sound pressure, and functions as a vibration electrode. When the membrane 13 vibrates due to the sound pressure, a capacitance (electrostatic capacitance) of a parallel plate capacitor (parallel plate condenser) formed by the backplate 16 and the membrane 13 changes. The MEMS microphone 10 detects sound by detecting a voltage change corresponding to the capacitance change. Specifically, the MEMS microphone 10 includes a power supply (not shown) that applies a bias voltage to the capacitor formed by the backplate 16 and the membrane 13, and a detection circuit (not shown) that detects the voltage change of the capacitor.

Here, in the present embodiment, a metal (e.g., molybdenum (Mo)) is used as the conductive layer 13B of the membrane 13, and a metal (e.g., molybdenum (Mo)) is used as the conductive layer 16A of the backplate 16.

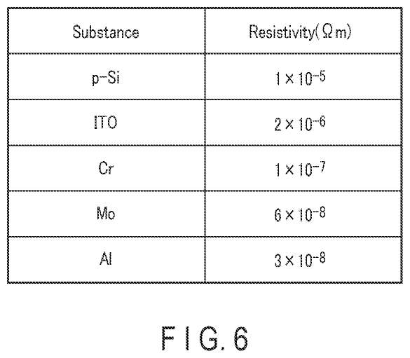

FIG. 6 is a diagram for explaining resistivities (Ωm) of a plurality of substances (conductive materials). FIG. 6 lists the resistivities of polysilicon (p-Si), ITO (indium tin oxide), chromium (Cr), molybdenum (Mo), and aluminum (Al).

Molybdenum (Mo) has a lower resistivity than polysilicon (p-Si), indium tin oxide (ITO), chromium (Cr), etc. Therefore, by using molybdenum (Mo) for the membrane 13 and the backplate 16, the resistance of the membrane 13 and the backplate 16 can be further reduced. Thus, the capacitance change between the membrane 13 and the backplate 16 can be accurately detected, and sensitivity of the MEMS microphone 10 can be improved. From the viewpoint of resistivity, it is also effective to use aluminum (Al) for the membrane 13 and the backplate 16.

Molybdenum (Mo) has a high corrosion resistance to an acidic solution such as hydrofluoric acid. Therefore, even when hydrofluoric acid is used in the step of forming the opening portion 11A in the glass substrate 11, corrosion of the membrane 13 and the backplate 16 can be suppressed, and deterioration of electrical characteristics of the membrane and the backplate 16 can be suppressed. From the viewpoint of corrosion resistance, molybdenum (Mo) is more suitable than aluminum (Al).

Molybdenum (Mo) and aluminum (Al) can be processed by dry etching. Thus, when the membrane 13 made of a laminated film is processed and the through holes are formed in the membrane 13, the manufacturing process is facilitated and the processing accuracy can be improved. Similarly, when the backplate 16 made of a laminated film is processed and the through holes are formed in the backplate 16, the manufacturing process is facilitated and the processing accuracy can be improved. The use of molybdenum (Mo), etc. for the membrane 13 and the backplate 16 is advantageous in the manufacturing process of the MEMS microphone 10.

### [1-3] Advantageous Effects of First Embodiment

As described above in detail, in the first embodiment, the MEMS microphone 10 includes the glass substrate 11 having the opening portion 11A, the membrane 13 provided on the glass substrate 11 so as to cover the opening portion 11A and including the conductive layer 13B, and the backplate 16 provided above the membrane 13 via the cavity 15, including a plurality of through holes through which sound waves pass, and including the conductive layer 16A. The conductive layer 13B is made of a metal or conductive oxide, and the conductive layer 16A is made of a metal or conductive oxide.

Therefore, according to the first embodiment, the resistance between the membrane electrode (the conductive layer 13B of the membrane 13) and the backplate electrode (the conductive layer 16A of the backplate 16) can be reduced. Thus, the sensitivity of the MEMS microphone 10 can be improved. For example, according to the first embodiment, the sensitivity of the MEMS microphone 10 can be improved as compared with the case where polysilicon is used for the membrane electrode and the backplate electrode.

The glass substrate 11 having an insulating property is used as a substrate of the MEMS microphone 10. Thus, a plurality of layers formed on the glass substrate 11 can be prevented from being short-circuited through the glass substrate 11. The glass substrate 11 is less expensive than a semiconductor substrate (e.g., a silicon substrate). Thus, the cost of the MEMS microphone 10 can be reduced.

The MEMS microphone 10 includes the wiring layer 26 electrically connected to the conductive layer 16A of the backplate 16. The insulating layer 24 made of, for example, silicon oxide (SiOx) is provided between the wiring layer 26 and the end portion of the membrane 13. Thus, the wiring layer 26 and the conductive layer 13B of the membrane 13 can be prevented from being short-circuited. In the region where the insulating layer 24 is disposed, the distance between the wiring layer 26 and the conductive layer 13B in the thickness direction can be increased. Thus, the parasitic capacitance can be reduced.

### [2] Second Embodiment

In the second embodiment, the membrane 13 has a two-layered structure including the conductive layer 13B and the insulating layer 13C.

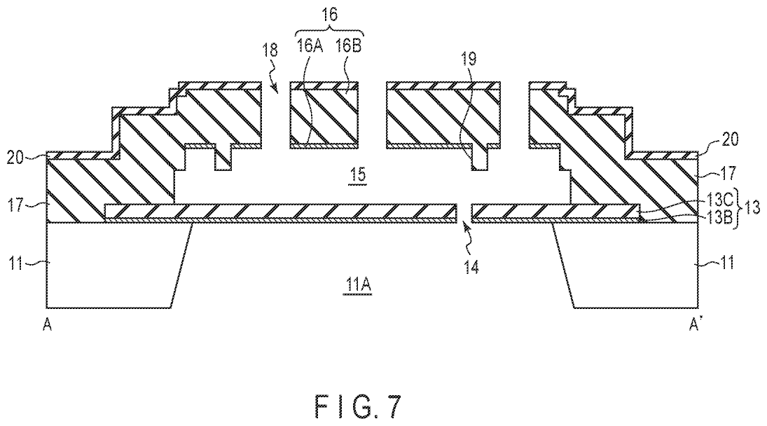

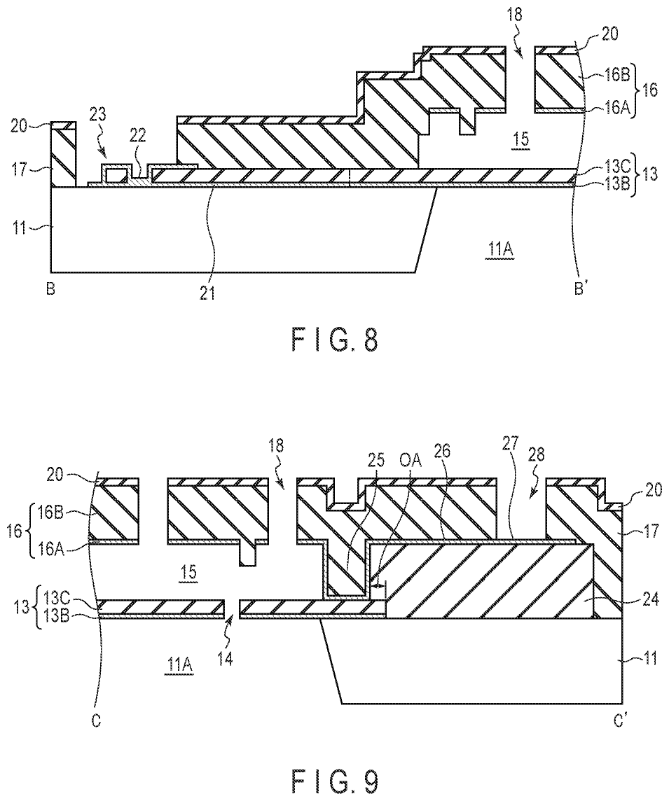

The plan view and the bottom view of the MEMS microphone 10 according to the second embodiment are the same as FIGS. 1 and 2 described in the first embodiment. FIGS. 7 to 9 are cross-sectional views of the MEMS microphone 10 according to the second embodiment. FIG. 7 is a cross-sectional view taken along line A-A′ shown in FIG. 1, FIG. 8 is a cross-sectional view taken along line B-B′ shown in FIG. 1, and FIG. 9 is a cross-sectional view taken along line C-C′ shown in FIG. 1.

The membrane 13 is provided on the glass substrate 11 so as to cover the opening portion 11A. The membrane 13 has a circular shape. The size of the membrane 13 is larger than that of the opening portion 11A of the glass substrate 11.

The membrane 13 has a two-layered structure in which the conductive layer 13B and the insulating layer 13C are sequentially stacked. The conductive layer 13B functions as an electrode (vibration electrode) of the membrane 13. The conductive layer 13B is provided in contact with the glass substrate 11. Since the glass substrate 11 has an insulating property, it is not a problem if the conductive layer 13B is in direct contact with the glass substrate 11. The conductive layer 13B and the insulating layer 13C are made of the material described in the first embodiment.

Also in the membrane terminal 22 shown in FIG. 8, an insulating layer corresponding to the insulating layer 13A is deleted. The other structures are the same as those in the first embodiment.

According to the second embodiment, the conductive layer 13B included in the membrane 13 can be directly formed on the glass substrate 11, and the membrane 13 can have a two-layered structure. Thus, the cost of the MEMS microphone 10 can be reduced.

In addition, since the thickness of the membrane 13 can be reduced, the membrane 13 easily vibrates according to the sound pressure. Thus, the sensitivity of the MEMS microphone 10 can be improved.

### [3] Third Embodiment

When a capacitance of a portion where a membrane (diaphragm) vibrates is Ci and a capacitance (parasitic capacitance) of a portion where a membrane does not vibrate is Cp, a capacitance of an entire MEMS microphone is “Ci+Cp”. Thus, when a capacitance change between the vibrating membrane and a backplate is detected, the parasitic capacitance Cp becomes a factor in deteriorating the sensitivity of the MEMS microphone. Therefore, in order to improve the sensitivity of the MEMS microphone, it is desirable to reduce the parasitic capacitance Cp. The third embodiment is a configuration example for reducing the capacitance (parasitic capacitance) of the portion where the membrane does not vibrate.

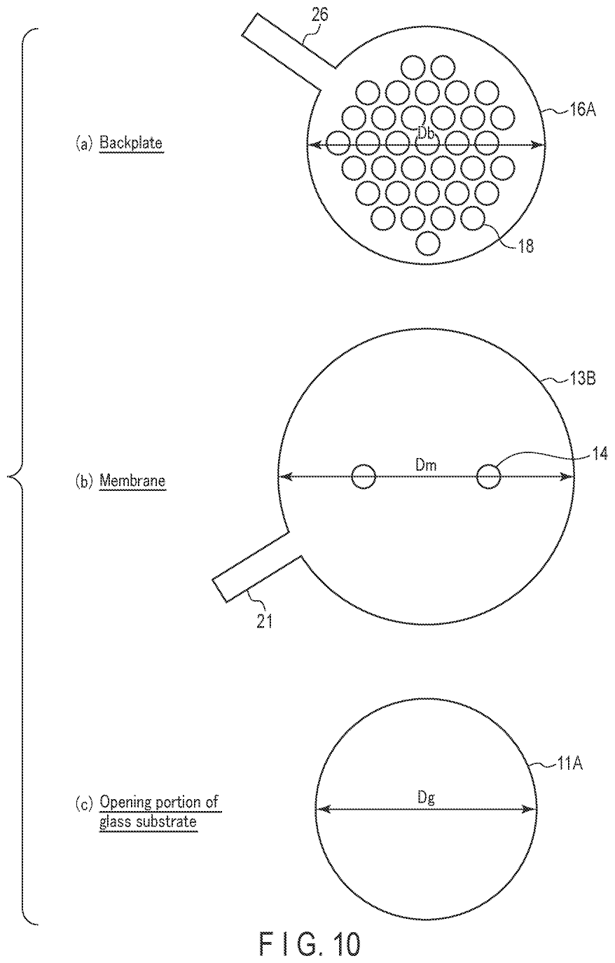

Hereinafter, the conductive layer 16A of the backplate 16 is referred to as a backplate electrode 16A, and the conductive layer 13B of the membrane 13 is referred to as a membrane electrode 13B. FIG. 10 is a plan view of the backplate electrode 16A, the membrane electrode 13B, and the opening portion 11A of the glass substrate 11 according to the third embodiment. That is, FIG. 10(a) is a plan view of the backplate electrode 16A, FIG. 10(b) is a plan view of the membrane electrode 13B, and FIG. 10(c) is a plan view of the opening portion 11A of the glass substrate 11. The cross-sectional structure of the MEMS microphone 10 is the same as that of the first embodiment or the second embodiment.

The diameter of the backplate electrode 16A is Db, the diameter of the membrane electrode 13B is Dm, and the diameter of the opening portion 11A of the glass substrate 11 is Dg. As described above, the diameter Dg of the opening portion 11A is the diameter (i.e., the minimum diameter) on the upper surface side of the glass substrate 11. The diameter Db of the backplate electrode 16A and the diameter Dm of the membrane electrode 13B satisfy a relationship of “Db<Dm”. For example, Db=1.1 mm and Dm=1.2 mm.

In addition, for example, the diameter Db of the backplate electrode 16A and the diameter Dg of the opening portion 11A satisfy a relationship of “Db>Dg”. For example, Dg=1.0 mm.

In the MEMS microphone 10 configured as such, the electrode portion of the non-vibrating region of the membrane electrode 13B does not constitute a capacitance. Accordingly, since the parasitic capacitance can be reduced, the sensitivity of the MEMS microphone 10 can be improved.

### [4] Fourth Embodiment

The fourth embodiment is another configuration example for reducing the parasitic capacitance of the MEMS microphone.

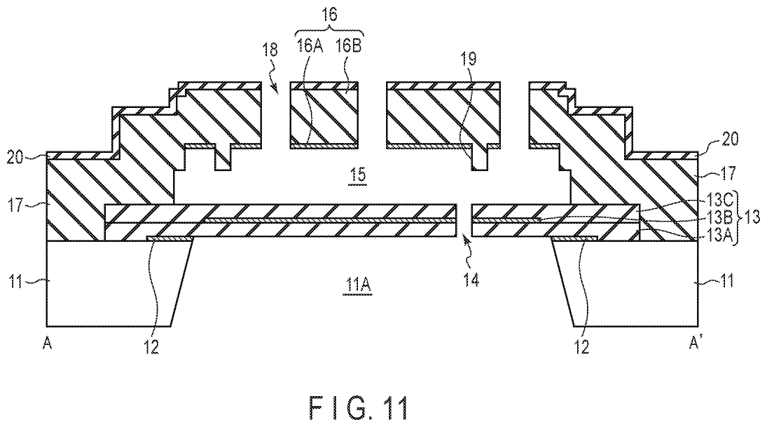

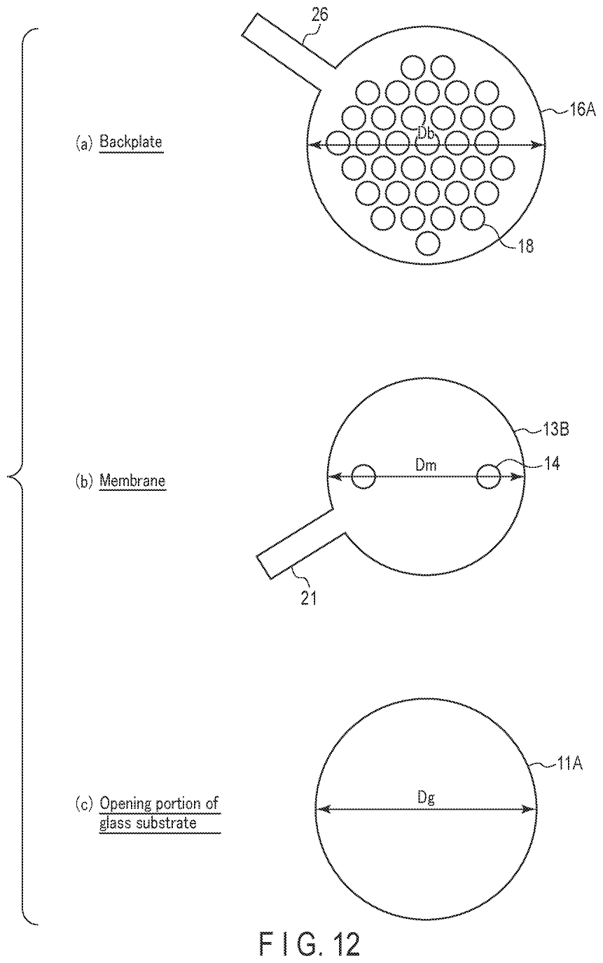

FIG. 11 is a cross-sectional view of the MEMS microphone 10 according to the fourth embodiment. FIG. 11 is a cross-sectional view taken along line A-A′ of FIG. 1. FIG. 12 is a plan view of the backplate electrode 16A, the membrane electrode 13B, and the opening portion 11A of the glass substrate 11 according to the fourth embodiment. That is, FIG. 12(a) is a plan view of the backplate electrode 16A, FIG. 12(b) is a plan view of the membrane electrode 13B, and FIG. 12(c) is a plan view of the opening portion 11A of the glass substrate 11.

The membrane 13 has a three-layered structure in which an insulating layer 13A, a conductive layer 13B, and an insulating layer 13C are sequentially stacked. The diameter of the conductive layer 13B is smaller than the diameters of the insulating layers 13A and 13C.

The diameter of the backplate electrode 16A is Db, the diameter of the membrane electrode 13B is Dm, and the diameter of the opening portion 11A of the glass substrate 11 is Dg. The diameter Dm of the membrane electrode 13B and the diameter Dg of the opening portion 11A satisfy a relationship of “Dm<Dg”. For example, Dm=1.0 mm and Dg=1.1 mm.

In addition, for example, the diameter Db of the backplate electrode 16A and the diameter Dg of the opening portion 11A satisfy a relationship of “Db>Dg”. For example, Db=1.2 mm.

In the MEMS microphone 10 configured as such, the entire membrane electrode 13B vibrates according to a sound pressure. In other words, the membrane electrode 13B does not include a non-vibrating region that becomes a parasitic capacitance. Accordingly, since the parasitic capacitance can be reduced, the sensitivity of the MEMS microphone 10 can be improved.

The present invention is not limited to the above-described embodiments, and the constituent elements can be modified and embodied without departing from the scope of the invention. Furthermore, the embodiments described above include inventions at various stages, and various inventions can be configured by an appropriate combination of a plurality of components disclosed in one embodiment or an appropriate combination of components disclosed in different embodiments. For example, even if some structural elements are deleted from all the structural elements disclosed in the embodiments, in the case where the problem to be solved by the invention can be solved and the effect of the invention can be obtained, an embodiment from which these structural elements are deleted can be extracted as an invention.

1. A MEMS microphone comprising:
a glass substrate including an opening portion;
a membrane provided on the glass substrate so as to cover the opening portion and including a first conductive layer; and
a backplate provided above the membrane via a cavity, including a plurality of through holes through which sound waves pass, and including a second conductive layer,
wherein
the first conductive layer is made of a metal or a conductive oxide, and
the second conductive layer is made of a metal or a conductive oxide.

2. The MEMS microphone according to claim 1, wherein
the first conductive layer is made of molybdenum (Mo), chromium (Cr), aluminum (Al), or indium tin oxide (ITO), and
the second conductive layer is made of molybdenum (Mo), chromium (Cr), aluminum (Al), or indium tin oxide (ITO).

3. The MEMS microphone according to claim 1, wherein
the membrane includes a first insulating layer provided under the first conductive layer and a second insulating layer provided on the first conductive layer.

4. The MEMS microphone according to claim 3, wherein
each of the first and second insulating layers is made of silicon nitride.

5. The MEMS microphone according to claim 1, wherein
the membrane includes a first insulating layer provided on the first conductive layer, and
the first conductive layer is in contact with the glass substrate.

6. The MEMS microphone according to claim 5, wherein
the first insulating layer is made of silicon nitride.

7. The MEMS microphone according to claim 1, wherein
the backplate includes a third insulating layer provided on the second conductive layer, and
the second conductive layer faces the membrane via the cavity.

8. The MEMS microphone according to claim 7, wherein
the third insulating layer is made of silicon nitride.

9. The MEMS microphone according to claim 1, further comprising a protective layer provided on the backplate.

10. The MEMS microphone according to claim 9, wherein
the protective layer is made of amorphous silicon.

11. The MEMS microphone according to claim 1, further comprising:
a wiring layer electrically connected to the second conductive layer; and
a fourth insulating layer provided between the membrane and the wiring layer.

12. The MEMS microphone according to claim 11, wherein
the fourth insulating layer is made of silicon oxide.

13. The MEMS microphone according to claim 1, wherein
a diameter of the second conductive layer is smaller than a diameter of the first conductive layer.

14. The MEMS microphone according to claim 1, wherein
a diameter of the first conductive layer is smaller than a diameter of the opening portion.
